(19) United States
(12) Patent Application Publication
(10) Pub. No.: US 2008/0122079 A1
(43) Pub. Date: May 29, 2008

(54) PACKAGE SUBSTRATE AND MANUFACTURING METHOD THEREOF

(75) Inventors: Bo-Wei Chen, Hsinchu (TW); Hsien-Shou Wang, Hsinchu (TW)

Correspondence Address: LOWE HAUPTMAN HAM & BERNER, LLP, 1700 DIAGONAL ROAD, SUITE 300, ALEXANDRIA, VA, 22314, US

(73) Assignee: PHOENIX PRECISION TECHNOLOGY CORPORATION, Hsinchu (TW)

(21) Appl. No.: 11/620,795

(22) Filed: Jan. 8, 2007

(30) Foreign Application Priority Data
Aug. 16, 2006 (TW) 095130053

(51) Int. Cl. H01L 23/48; H01L 23/29; H01L 21/44

(52) U.S. Cl. 257/737; 257/777; 438/653; 257/E23.021; 257/E23.172; 257/E21.598

(57) ABSTRACT

The package substrate of the present invention comprises a carrying board, bump pads, wire bonding pads, a solder mask, metallic bumps, and a metallic protective layer. The solder pads and the wire bonding pads are disposed on the surface of the carrying board. The solder mask is patterned to expose bump pads, wire bonding pads, and part of the surface of the substrate on the periphery of the wire bonding pads. The metallic bumps are disposed on the surface of the bump pads and extend to the surface of the solder mask. The metallic protective layer is disposed on the surfaces of the metallic bumps and the wire bonding pads. Besides, a method for manufacturing this package substrate, a semiconductor package structure comprising this package substrate, and a manufacturing method thereof are disclosed. Therefore, the manufacturing process of the package substrate is simple, and the package substrate is slim.

### BACKGROUND OF THE INVENTION

1. Field of the Invention

The present invention relates to method for manufacturing a structure of a package substrate, more particularly, to a structure of a flip chip substrate having improved density of circuit arrangement without plating through holes and a manufacturing method of a structure of a package substrate to simplify the process.

2. Description of Related Art

In the development of electronics, the design trend of electronic devices is towards to multifunction and high-performance. Thus, high-density integration and miniaturization are necessary for a semiconductor package structure. On the ground of reason aforementioned, the mono-layered circuit boards providing active components, passive components, and circuit connection, are being replaced by the multi-layered circuit boards. The area of circuit arrangement on the circuit board increases in a restricted space by interlayer connection to meet with the requirement of high-density integration.

The conventional semiconductor package structure is fabricated by adhering a semiconductor chip on the top surface of the substrate, wire bonding or flip chip package, and then forming solder balls on the back surface of the substrate to electrically connect with the outer electric devices. Although more connecting ends are provided, the performance of electronic devices cannot be enhanced but is in fact restricted, owing to the over-long path of lines and then high resistance for high frequency operation. Furthermore, the repeated interlayer connection of the conventional package aggravates the complexity of the process.

In the conventional method for manufacturing a structure of a package substrate, a core-board is provided first, and then the structure of the inner layer is accomplished by drilling, plating metal, plugging holes, shaping circuits and so on. Subsequently, a multilayered package substrate is accomplished by build-up layer technology. One of methods for manufacturing a multilayered circuit board of build-up layers is shown in FIGS. 1A to 1E. As shown in FIG. 1A, a core-board 11, comprising a core layer 111 of predetermined thickness and a first circuit layer 112 on the surface of the core layer 111, is provided first. At the same time, a plurality of plating through holes 113 are formed in the core layer 111. Accordingly, the first circuit layers 112 on the top surface and the back surface of the core layer 111 are connected to each other through the plating through holes 113. As shown in FIG. 1B, a process increasing circuit layers is performed on the core-board 11 to dispose a dielectric layer 12 on the surface of the core-board 11, wherein a plurality of blind holes 13 are formed in the dielectric layer 12 to connect with the first circuit layer 112. As shown in FIG. 1C, a conductive layer 14 is formed on the surface of the dielectric layer 12 by electroless plating or sputtering, and a barrier layer 15 is formed on the surface of the conductive layer 14. Wherein, the barrier layer 15 is patterned and a plurality of openings 150 are formed to expose the part surface of the conductive layer 14. As shown in FIG. 1D, a patterned second circuit layer 16 and a conductive blind hole 13a are formed, wherein the second circuit layer 16 can be connected to the first circuit layer 112 through the conductive blind hole 13a. Then, the barrier layer 15 and the partial conductive layer 14 covered by the barrier layer are removed. Thereby, a first build-up layer 10a is accomplished. As shown in 1E, a second build-up layer 10b can be formed on the surface of the first build-up layer 10a by the above process and a multilayer package substrate 10 is accomplished.

In the aforementioned method of providing a core board, then accomplishing the inner structure by drilling, plating metal, plugging holes, shaping the circuit and so on, and subsequently, realizing a multilayered package substrate by build-up layer technology, some drawbacks exist such as low density of circuit arrangement, excessive layers, long wires, and high resistance. Thereby, the electric property is poor in high frequency operation; in addition, the excessive layers result in the complex processing and high manufacturing cost.

### SUMMARY OF THE INVENTION

In order to resolve the aforementioned disadvantages, the present invention provides a structure of a package substrate, comprising: a carrying board, and a substrate structure formed on the surface of the carrying board; wherein the substrate structure comprises: a plurality of bump pads and a plurality of wire bonding pads, wherein the bump pads and the wire bonding pads are disposed on the surface of the carrying board; a solder mask formed on the surface of the carrying board, wherein the solder mask is patterned to expose the bump pads and the wire bonding pads; a plurality of metallic bumps, disposed on the surface of the bump pads and extending to the surface of the solder mask; and a metallic protective layer, disposed on the surfaces of the metallic bumps and the wire bonding pads.

In the aforementioned structure of a package substrate, the material of the carrying board can be metal. Preferably, the carrying board is a resin coated copper plate or a metal plate which is not resin coated.

In the structure of a package substrate of the present invention, the bump pads and the wire bonding pads individually comprise an etching-stop layer and a metal layer. Wherein, the material of the etching-stop layer, which can protect the metal layer form being etched, is not limited. Preferably, the material of the etching-stop layer is gold, nickel, palladium, silver, tin, nickel/palladium, chromium/titanium, nickel/gold, palladium/gold, nickel/palladium/gold or a combination thereof. The material of the metal layer is not limited. Preferably, the material of the metal layer is copper, nickel, chromium, titanium, a copper/chromium alloy, or a tin/lead alloy.

The patterned solder mask of the present invention is used for protecting the structure of the package substrate from being damaged. On the other hand, the connection between solder balls, caused by the adhesion of solder material on the surface of the patterned solder mask, is avoided. The material of the solder mask is not limited. Preferably, the material of the solder mask is green paint or black paint.

In the present invention, the material of the metallic bumps, disposed on the surface of the bump pads and extending to the part surface of the solder mask, is not limited. Preferably, the material of the metallic bumps is copper, nickel, chromium, titanium, a copper/chromium alloy, or a tin/lead alloy.

The present invention further provides a semiconductor package structure, comprising a substrate structure, wherein the substrate structure comprises a plurality of bump pads, a plurality of wire bonding pads, a solder mask, a plurality of metallic bumps, and a metallic protective layer formed on the surfaces of the metallic bumps and the wire bonding pads, and the solder mask is patterned to expose the surfaces of the bump pads and the wire bonding pads, the metallic bumps are disposed on the surface of the bump pads and extend to the part surface of the solder mask, and the metallic protective layer is disposed on the surfaces of the metallic bumps and the wire bonding pads; at least two chips electrically connected to the substrate structure via a plurality of solder bumps and a plurality of metal wires, wherein the solder bumps are disposed on the position corresponding to the metallic bumps, and the metal wires are disposed on the position corresponding to the wire bonding pads; a first resin region, wherein the region comprising the solder bumps is filled with a resin; and a second resin region covering the overall surface of the substrate structure comprising the chips.

In the semiconductor package structure of the present invention, at least one of the chips is electrically connected to the wire bonding pads through the metal wires and at least another of the chips is electrically connected to the bump pads through the solder bumps.

The aforementioned substrate structure and the semiconductor package structure of the present invention can be provided by the following steps, but not limited thereto: (A) providing a carrying board; (B) forming a first barrier layer on the surface of the carrying board, wherein the first barrier layer is patterned to form a plurality of first openings; (C) forming an etching-stop layer and a metal layer in the first openings; (D) removing the first barrier layer; (E) forming a solder mask on the surface of the carrying board, wherein the solder mask is patterned, a plurality of second openings of the patterned solder mask are formed to expose the etching-stop layer, the metal layer and the part surface of the carrying board, and a plurality of third openings of the patterned solder mask are formed to expose the surface of the metal layer; (F) forming a second barrier layer, wherein the second barrier layer is patterned and a plurality of fourth openings are formed to corresponding to expose the metal layer in the third openings; (G) forming a plurality of metallic bumps in the fourth openings; (H) removing the second barrier layer; and (I) forming a metallic protective layer on the surfaces of the metallic bumps, the etching-stop layer and the metal layer in the second openings.

In the manufacturing method of the present invention, a plurality of solder bumps and a plurality of metal wires are formed to electrically connect the metallic protective layer to at least two chips; subsequently, the substrate structure is molded to accomplish the semiconductor package structure with chips.

After accomplishing the above steps, the carrying board of the semiconductor package structure can be removed.

Thereby, the present invention resolves the drawbacks of relevant prior art, such as low density of circuit arrangement, excessive layers, long wires, and high resistance. The structure of the present invention without plating through holes can enhance the density of circuit arrangement, simplify the process, and reduce the thickness of the package substrate. Thus, the present invention meets with the requirement of miniaturization.

According to the aforementioned manufacturing method of a structure of a package substrate in the present invention, the material of the first barrier layer and the second barrier layer is not limited. Preferably, the first barrier layer and the second barrier layer are dry films or liquid photo resist films.

According to the aforementioned manufacturing method of a structure of a package substrate in the present invention, the method for forming the first and fourth openings is not limited. Preferably, the method for forming the first and fourth openings is a process with exposure and development.

According to the aforementioned manufacturing method of a structure of a package substrate in the present invention, the method for forming the etching-stop layer is not limited. Preferably, the method for forming the etching-stop layer is sputtering, evaporation, electroless plating, electroplating, or chemical vapor deposition.

According to the aforementioned manufacturing method of a structure of a package substrate in the present invention, the method for forming the second and third openings is not limited. Preferably, the method for forming the second and third openings is a process with exposure and development.

According to the aforementioned manufacturing method of a structure of a package substrate in the present invention, the method for forming the metallic bumps is not limited. Preferably, the method for forming the metallic bumps is electroplating.

According to the aforementioned manufacturing method of a structure of a package substrate in the present invention, the method for forming the metallic protective layer is not limited. Preferably, the method for forming the metallic protective layer is sputtering, evaporation, electroless plating, electroplating, or chemical vapor deposition.

According to the aforementioned manufacturing method of a structure of a package substrate in the present invention, the method for removing the carrying board is not limited. Preferably, the method for removing the carrying board is etching.

Other objects, advantages, and novel features of the invention will become more apparent from the following detailed description when taken in conjunction with the accompanying drawings.

### BRIEF DESCRIPTION OF THE DRAWINGS

FIGS. 1A to 1E are cross-section views of a conventional method of manufacturing a package substrate having a core-board;

FIGS. 2A to 2K are cross-section views of manufacturing a structure of a package substrate of a preferred embodiment; and

FIG. 2L is a top view of a structure of a semiconductor package substrate of a preferred embodiment.

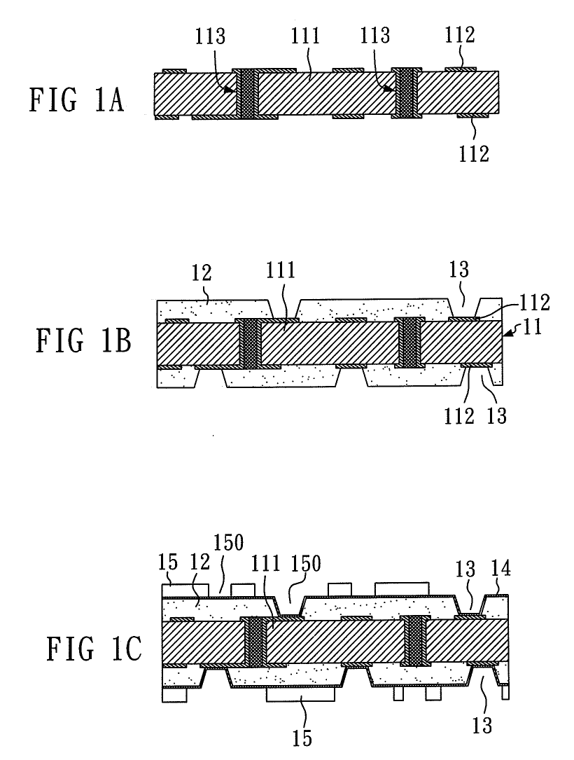

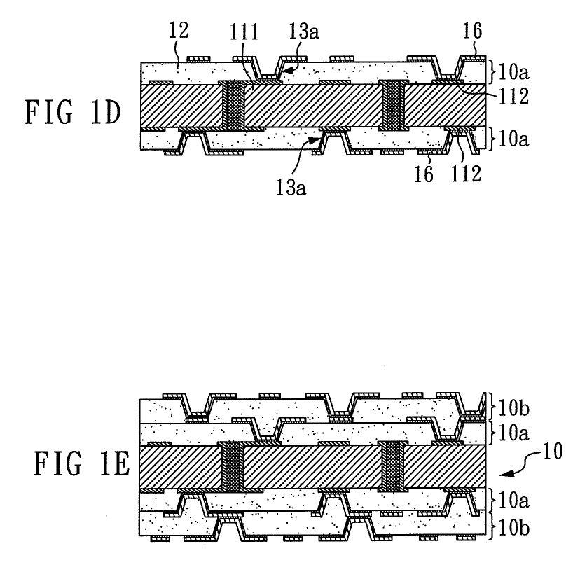

### DETAILED DESCRIPTION OF THE PREFERRED EMBODIMENT

### Embodiment 1

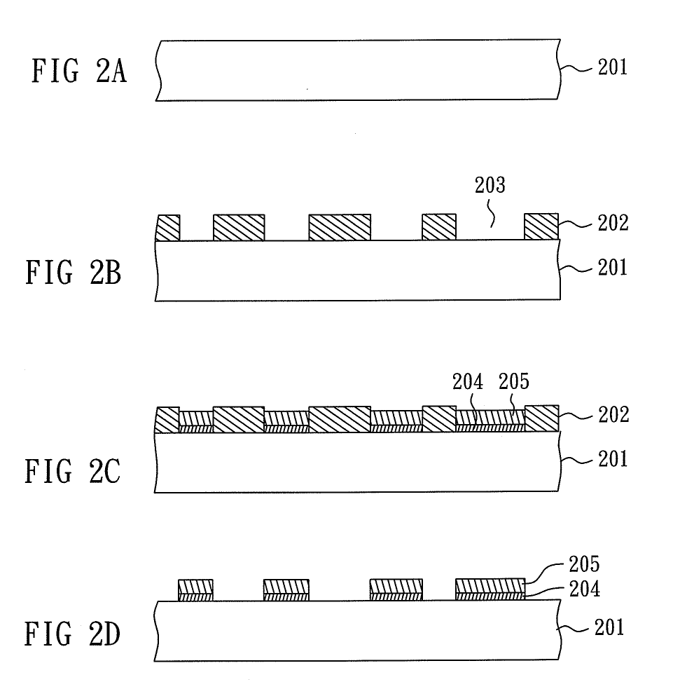

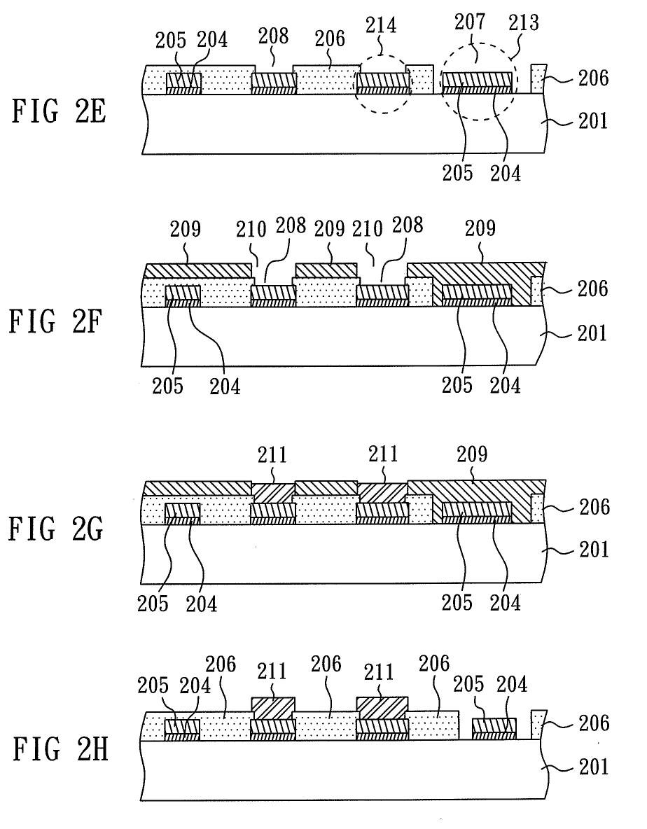

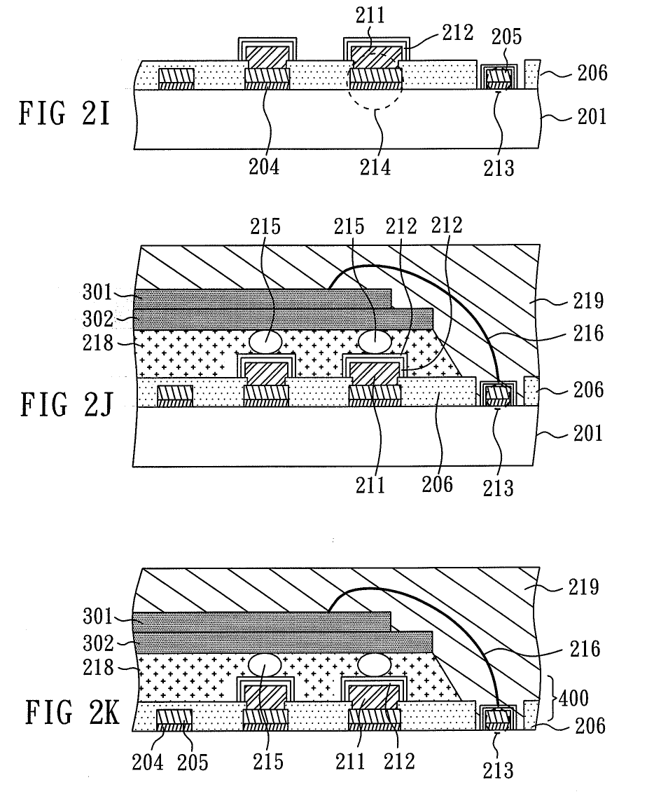

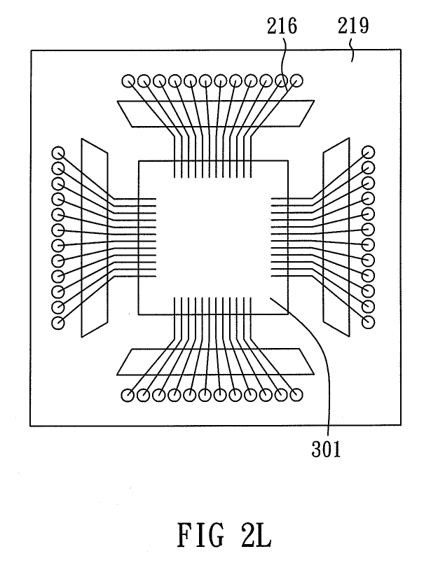

As shown in FIG. 2A, a carrying board 201 is provided first. The carrying board 201 can be a resin coated copper plate or a metal plate which is not resin coated. Preferably, the carrying board 201 is a metal plate in the present embodiment. Subsequently, as shown in FIG. 2B, a dry film or a liquid photo resist film forms a first barrier layer 202. The first barrier layer 202 is patterned to form a plurality of first openings 203 by exposure and development. In the present embodiment, the first patterned barrier layer 202 formed on the surface of the carrying board 201 is a dry film. Then, as shown in FIG. 2C, an etching-stop layer 204 and a metal layer 205 are formed in sequence on the surface of the carrying board 201 in the a plurality of first openings 203 by electroplating. The material of the etching-stop layer 204 can be gold, nickel, palladium, silver, tin, nickel/palladium, chromium/titanium, nickel/gold, palladium/gold, nickel/palladium/gold or combination thereof. Preferably, the material of the etching-stop layer 204 is gold in the present embodiment. The material of the metal layer 205 can be copper, nickel, chromium, titanium, a copper/chromium alloy, or a tin/lead alloy. Preferably, the material of the metal layer 205 is copper in the present embodiment. Subsequently, as shown in FIG. 2D, the first barrier layer 202 is removed.

Next, as shown in FIG. 2E, a patterned solder mask 206 is formed. The solder mask 206 can be green paint or black paint. Preferably, the solder mask 206 is green paint in the present embodiment. In addition, the solder mask 206 of the present embodiment comprises a plurality of second openings 207 and third openings 208. The openings are formed by exposure and development. The second openings 207 of the present embodiment are formed to expose the etching-stop layer 204, the metal layer, and the part surface of the carrying board. The etching-stop layer 204 and the metal layer 205 in each second opening 207 can serve as a wire bonding pad 213. The third openings 208 are formed to expose the metal layer 205. The metal layer 205 and the etching stop layer 204 in each third opening 208 can serve as a bump pad 214.

As shown in FIG. 2F, a second barrier layer 209 is patterned and a plurality of fourth openings 210 are formed to expose the metal layer 205 in the third openings 208.

Next, as shown in FIG. 2G, a plurality of metallic bumps 211 are formed in the fourth openings 210 by electroplating. The material of the metallic bumps can be copper, nickel, chromium, titanium, a copper/chromium alloy, or a tin/lead alloy. Preferably, the material of the metallic bumps is copper in the present embodiment. Subsequently, the second barrier layer 209 is removed, as shown in FIG. 2H.

As shown in FIG. 2I, a metallic protective layer 212 is formed on the surfaces of the metallic bumps 211 and the metal layer 205 by electroplating. The material of the metallic protective layer 212 can be nickel/palladium, chromium/titanium, nickel/gold, palladium/gold, nickel/palladium/gold, or combination thereof. Preferably, the material of the metallic protective layer 212 is nickel/gold in the present embodiment.

In summary, the present invention provides a structure of a package substrate 400 (as shown in FIG. 2I), comprising: a carrying board 201; and a substrate structure 402 formed on the carrying board 201, wherein the substrate structure 402 comprises: a plurality of bump pads 214, at least one wire bonding pad 213, a solder mask 206, a plurality of metallic bumps 211, and a metallic protective layer 212. The bump pads 214 and the wire bonding pads 213 are disposed on the surface of the carrying board 201. The solder mask 206 is patterned to expose the bump pads 214, the wire bonding pads 213, and the surface of the carrying board 201 surrounding the wire bonding pads 213. The a plurality of metallic bumps 211 are disposed on the surface of the bump pads 213 and extend to the part surface of the solder mask 206. The metallic protective layer 212 is disposed on the surfaces of the metallic bumps 211 and the wire bonding pads 213.

### Embodiment 2

After accomplishing the step of FIG. 2I, a plurality of solder bumps 215 and at least one metal wire 216 (gold wire) are formed to electrically connect the metallic protective layer 212 of the aforementioned structure of a package substrate 400 to two chips 302 and 301. The chip 302 is connected to the solder bumps 215 disposed on the position corresponding to the metal bumps 211 by reflow. The chip 301 is connected to the wire bonding pads 213 via a plurality of metal wires 216. As a result, the chips 301 and 302 are electrically connected to the substrate structure 402. Subsequently, the region comprising the solder bumps 215 is filled with a resin to form a first resin region 218. Also, the region comprising the metal wires 216 is filled with another resin to form a second resin region 219 and a structure shown in FIG. 2J is accomplished. Finally, as shown in FIG. 2K, the carrying board 201 is removed by etching. Thereby, a semiconductor package structure of the present invention is accomplished. FIG. 2K is a cross-section view of a semiconductor package structure, including the chips 301 and 302 connected to the substrate structure 402. FIG. 2L is a top view of a semiconductor package structure.

The present invention further provides a semiconductor package structure 400 (as shown in FIGS. 2K and 2L), comprising: a substrate structure 402; chips 301 and 302; a first resin region 218; and a second resin region 219. The substrate structure 202 comprises a plurality of bump pads 214, at least one wire bonding pad 213, a solder mask 206, a plurality of metallic bumps 211, and a metallic protective layer 212. The solder mask 206 is patterned to expose the bump pads 214, the wire bonding pads 213, and the part surface of the carrying board 201 surrounding the wire bonding pads 213. The a plurality of metallic bumps 211 are disposed on the surface of the bump pads 214 and extend to the part surface of the solder mask 206. The metallic protective layer 212 is disposed on the surfaces of the metallic bumps 211 and the wire bonding pads 213. In addition, the chips 301 and 302 are electrically connected to the substrate structure 402 without the carrying board 201 through a plurality of solder bumps 215 and metal wires 216. The solder bumps 215 are disposed on the position corresponding to the metallic bumps 211, and the metal wires 216 are disposed on the position corresponding to the wire bonding pads 213. The first resin region 218 is formed by filling the region comprising the solder bumps 215 with a resin. The second resin region 219 is formed by filling the region comprising the metal wires 216 with a resin.

Thereby, the present invention resolves the drawbacks in the prior art, such as low density of circuit arrangement, excessive layers, long wires, and high resistance. Since the structure of the present invention does not comprise plating through holes, the process of drilling, plating metal, plugging holes, shaping circuit and so on is eliminated and the area of circuit arrangement increases. In conclusion, the present invention can enhance the density of circuit arrangement, simplify the process, and reduce the thickness of the package substrate. Thus, the present invention meets with the requirement of miniaturization.

Although the present invention has been explained in relation to its preferred embodiment, it is to be understood that many other possible modifications and variations can be made without departing from the spirit and scope of the invention as hereinafter claimed.

What is claimed is:

1. A structure of a package substrate, comprising:
a carrying board and a substrate structure formed on the surface of the carrying board, wherein the substrate structure comprises:
a plurality of bump pads and a plurality of wire bonding pads, wherein the bump pads and the wire bonding pads are disposed on the surface of the carrying board;
a solder mask, formed on the surface of the carrying board, wherein, the solder mask is patterned to expose the bump pads and the wire bonding pads;
a plurality of metallic bumps, disposed on the surface of the bump pads and extending to the part surface of the solder mask; and
a metallic protective layer, disposed on the surfaces of the metallic bumps and the wire bonding pads.

2. The structure of a package substrate as claimed in claim 1, wherein the bump pads and the wire bonding pads individually comprise an etching-stop layer and a metal layer.

3. The structure of a package structure as claimed in claim 1, wherein the carrying board is a resin coated copper plate or a metal plate.

4. The structure of a package structure as claimed in claim 2, wherein the material of the etching-stop layer is gold, nickel, palladium, silver, tin, nickel/palladium, chromium/titanium, nickel/gold, palladium/gold, nickel/palladium/gold or a combination thereof.

5. The structure of a package structure as claimed in claim 2, wherein the material of the metal layer is copper, nickel, chromium, titanium, a copper/chromium alloy, or a tin/lead alloy.

6. The structure of a package structure as claimed in claim 1, wherein the material of the metallic bumps is copper, nickel, chromium, titanium, a copper/chromium alloy, or a tin/lead alloy.

7. The structure of a package structure as claimed in claim 1, wherein the material of the metallic protective layer is nickel/palladium, chromium/titanium, nickel/gold, palladium/gold, nickel/palladium/gold, or a combination thereof.

8. The structure of a package structure as claimed in claim 1, wherein the solder mask is green paint or black paint.

9. A semiconductor package structure, comprising:
a substrate structure, comprising a plurality of bump pads, a plurality of wire bonding pads, a solder mask, a plurality of metallic bumps, and a metallic protective layer formed on the surfaces of the metallic bumps and the wire bonding pads, wherein the metallic bumps are disposed on the surface of the bump pads and extend to the part surface of the solder mask, and the metallic protective layer is disposed on the surfaces of the metallic bumps and the wire bonding pads;
at least two chips, electrically connected to the substrate structure via a plurality of solder bumps and a plurality of metal wires, wherein the solder bumps are disposed on the position corresponding to the metallic bumps, and the metal wires are disposed on the position corresponding to the wire bonding pads;
a first resin region, formed by filling the region comprising the solder bumps with the resin; and
a second resin region, covering the overall surface of the substrate structure comprising the chips.

10. The semiconductor package structure as claimed in claim 9, wherein at least one of the chips is electrically connected to the wire bonding pads through metal wires and at least another of the chips is electrically connected to the bump pads through the solder bumps.

11. The semiconductor package structure as claimed in claim 9, wherein the bump pads and the wire bonding pads individually comprise an etching-stop layer and a metal layer.

12. The semiconductor package structure as claimed in claim 11, wherein the material of the etching-stop layer is gold, nickel, palladium, silver, tin, nickel/palladium, chromium/titanium, nickel/gold, palladium/gold, nickel/palladium/gold or a combination thereof.

13. The semiconductor package structure as claimed in claim 11, wherein the material of the metal layer is copper, nickel, chromium, titanium, a copper/chromium alloy, or a tin/lead alloy.

14. The semiconductor package structure as claimed in claim 9, wherein the material of the metallic bumps is copper, nickel, chromium, titanium, a copper/chromium alloy, or a tin/lead alloy.

15. The semiconductor package structure as claimed in claim 9, wherein the material of the metallic protective layer is nickel/palladium, chromium/titanium, nickel/gold, palladium/gold, nickel/palladium/gold, or a combination thereof.

16. A method of manufacturing a structure of a package substrate, comprising:
(A) providing a carrying board;
(B) forming a first patterned barrier layer on the surface of the carrying board, wherein the first patterned barrier layer comprises a plurality of first openings;
(C) forming an etching-stop layer and a metal layer in sequence in the first openings;
(D) removing the first barrier layer;
(E) forming a solder mask on the surface of the carrying board, wherein the solder mask is patterned, a plurality of second openings of the patterned solder mask are formed to expose the etching-stop layer, the metal layer and the part surface of the carrying board; and a plurality of third openings of the patterned solder mask are formed to expose the surface of the metal layer;
(F) forming a second barrier layer, wherein the second barrier layer is patterned and a plurality of fourth openings are formed to expose the metal layer in the third openings;
(G) forming a plurality of metallic bumps in the fourth openings;
(H) removing the second barrier layer; and
(I) forming a metallic protective layer on the surfaces of the metallic bumps, the etching-stop layer, and the metal layer in the second openings.

17. The method of manufacturing a structure of a package substrate as claimed in claim 16, wherein before the step (F), forming a second patterned barrier layer, a conductive layer is formed on the surface of the patterned solder mask.

18. The method of manufacturing a structure of a package substrate as claimed in claim 16, further comprising the following steps after the step (I), forming a metallic protective layer:
(J) forming a plurality of solder bumps and a plurality of metal wires, electrically connected to at least two chips; and
(K) molding the substrate structure.

19. The method of manufacturing a structure of a package substrate as claimed in claim 18, further comprising a step after the step (K), molding the substrate structure:
(L) removing the carrying board.

20. The method of manufacturing a structure of a package substrate as claimed in claim 16, wherein the first barrier layer and the second barrier layer are dry films or liquid photo resist films.

21. The method of manufacturing a structure of a package substrate as claimed in claim 16, wherein the first, second, third, and fourth openings are formed by exposure and development.

22. The method of manufacturing a structure of a package substrate as claimed in claim 16, wherein the etching-stop layer is formed by sputtering, evaporation, electroless plating, electroplating, or chemical vapor deposition.

23. The method of manufacturing a structure of a package substrate as claimed in claim 16, wherein the metal layer is formed by electroplating.

24. The method of manufacturing a structure of a package substrate as claimed in claim 16, wherein the metallic bumps are formed by electroplating.

25. The method of manufacturing a structure of a package substrate as claimed in claim 16, wherein the metallic protective layer is formed by sputtering, evaporation, electroless plating, electroplating, or chemical vapor deposition.

26. The method of manufacturing a structure of a package substrate as claimed in claim 19, wherein the carrying board is removed by etching.
